(19) United States
(12) Patent Application Publication
(10) Pub. No.: US 2026/0362920 A1
(43) Pub. Date: Nov. 12, 2026

(54) ELECTRONIC APPARATUS AND METHOD OF MANUFACTURING THE SAME

(71) Applicant: Samsung Display Co., Ltd., Yongin-si (KR)

(72) Inventors: Eui Jeong KANG, Yongin-si (KR); Seeook LEE, Yongin-si (KR)

(73) Assignee: Samsung Display Co., Ltd., Yongin-si (KR)

(21) Appl. No.: 19/446,286

(22) Filed: Jan. 12, 2026

(30) Foreign Application Priority Data
May 9, 2025 (KR) 10-2025-0060238

(51) Int. Cl. H10K 59/131; H10K 59/12; H10K 59/121; H10K 59/80

(52) U.S. Cl. CPC H10K 59/131; H10K 59/1201; H10K 59/1213; H10K 59/873

(57) ABSTRACT

An electronic apparatus includes a substrate, a circuit element layer disposed on the substrate and including a pixel driver including a transistor and a component driver spaced apart from the pixel driver, a display element layer disposed on the circuit element layer and including a light emitting element connected to the pixel driver, an encapsulation layer disposed on the display element layer, a first electronic component disposed on the substrate, and a connection member electrically connecting the component driver and the first electronic component. The component driver includes a wiring layer and a pad disposed on the wiring layer and contacting the connection member. The wiring layer is disposed at a same layer as a gate electrode of the transistor.

### CROSS-REFERENCE TO RELATED APPLICATIONS

This application claims priority to and the benefit of Korean Patent Application No. 10-2025-0060238, filed on May 9, 2025 in the Korean Intellectual Property Office, the disclosure of which is incorporated by reference herein in its entirety.

### BACKGROUND

### Field

The disclosure relates to an electronic apparatus and a method of manufacturing the same. More particularly, the disclosure relates to an electronic apparatus with a reduced bezel and a method of manufacturing the same.

### Description of the Related Art

An electronic apparatus performs functions such as displaying images or sensing external signals, and includes various devices controlled by electrical signals. The electronic apparatus necessarily includes a circuit board on which various electronic components are mounted, and thus, various functions are implemented. Recently, the electronic apparatus is being developed towards providing high-resolution image display functions or becoming multi-functional. Accordingly, the number of electronic components mounted on the circuit board increases, and a signal wiring structure becomes more complex. These changes lead to an increase in the manufacturing cost of the circuit board, and in some cases, also cause an increase in the overall thickness of the electronic apparatus as a size of the circuit board increases or the circuit board is assembled into a curved shape.

### SUMMARY

The disclosure provides an electronic apparatus with reduced bezel size and thickness and a method of manufacturing the same.

One or more embodiments of the disclosure provide an electronic apparatus which may include a substrate, a circuit element layer disposed on the substrate and including a pixel driver including a transistor and a component driver spaced apart from the pixel driver, a display element layer disposed on the circuit element layer and including a light emitting element connected to the pixel driver, an encapsulation layer disposed on the display element layer, a first electronic component disposed on the substrate, and a connection member electrically connecting the component driver and the first electronic component. The component driver includes a wiring layer and a pad disposed on the wiring layer and contacting the connection member. The wiring layer is disposed at the same layer as a gate electrode of the transistor.

The component driver is spaced apart from the encapsulation layer in plan view.

The wiring layer includes a first wiring layer disposed at the same layer as the gate electrode and a second wiring layer disposed between the first wiring layer and the pad, and the first wiring layer, the second wiring layer, and the pad are connected to each other through an insulating layer.

The pad includes at least one of titanium (Ti), aluminum (Al), and molybdenum (Mo).

An insulating layer including an opening is disposed between the wiring layer and the pad, and the pad is electrically connected to the wiring layer through the opening.

The connection member is an anisotropic conductive film including a solder.

The electronic apparatus further includes a circuit board on which a second electronic component is mounted.

The electronic apparatus further includes a first connection line connecting the component driver and a gate driver, a second connection line connecting the component driver and a driving chip, and a third connection line connecting the component driver and the display element layer.

One or more embodiments of the disclosure provide an electronic apparatus which may include a substrate including a display area and a driving area, a driving chip disposed in the driving area, a first electronic component disposed in the driving area, and a connection member disposed between the substrate and the first electronic component. The driving area includes a chip pad part connected to the driving chip and including a first layer and a second layer disposed on the first layer and a component driver connected to the first electronic component. The component driver includes a wiring layer including a plurality of conductive layers and a plurality of component pads disposed on the wiring layer and coming into contact with the connection member. At least one of the conductive layers is disposed at the same layer as the first layer, and the component pads are disposed at the same layer as the second layer.

The chip pad part and the component pads include at least one of titanium (Ti), aluminum (Al), and molybdenum (Mo).

An insulating layer including an opening is disposed between the wiring layer and the component pads, and the component pads are electrically connected to the wiring layer through the opening.

The connection member is an anisotropic conductive film including a solder.

The electronic apparatus further includes a circuit board on which a second electronic component is mounted.

The driving area includes a recess portion having a concave shape in plan view, and the circuit board is disposed at the recess portion.

One of more embodiments of the disclosure provide a method of manufacturing an electronic apparatus. The method may include forming a circuit element layer on a substrate including a display area and a driving area, forming a display element layer on the circuit element layer, forming an encapsulation layer on the display element layer, and bonding an electronic component to the circuit element layer using a connection member. The forming of the circuit element layer includes forming a transistor in the display area and forming a wiring layer in the driving area. The forming of the wiring layer is simultaneously performed with the forming of the transistor.

The method further includes bonding a driving chip to the circuit element layer, and the bonding the electronic component is performed after the bonding of the driving chip.

The connection member is an anisotropic conductive film including a solder.

The bonding the electronic component is performed at a temperature from 140 degrees Celsius to 180 degrees Celsius.

The bonding the electronic component includes pressing the electronic component using a silicon pad to allow the electronic component to contact the circuit element layer and applying a heat to a lower portion of the substrate to form an electrical connection between the electronic component and the circuit element layer.

The method further includes grinding at least one side of the substrate to form a portion having a concave shape in plan view and forming a circuit board, and the circuit board is disposed at the portion having the concave shape.

According to the above, a separate circuit board to mount the electronic components is not needed, and thus, the thickness of the display module is reduced.

In addition, since an additional process to connect the circuit board and a display panel is unnecessary, the manufacturing process is simplified, and the manufacturing cost is reduced. Further, a border area of the display panel is reduced, and the electronic apparatus has a narrower bezel.

### BRIEF DESCRIPTION OF DRAWINGS

FIG. 1 is a block diagram of an electronic apparatus according to one or more embodiments;

FIG. 2 is a schematic view of electronic apparatuses according to embodiments of the present disclosure;

FIG. 3 is a perspective view of an electronic apparatus according to one or more embodiments;

FIG. 4 is an exploded perspective view of an electronic apparatus according to one or more embodiments;

FIG. 5 is a cross-sectional view of a display module taken along a line I-I’ of FIG. 4 according to one or more embodiments;

FIG. 6A is a plan view of a display module according to one or more embodiments;

FIG. 6B is a plan view of a layer of the display module of FIG. 6A according to one or more embodiments;

FIG. 6C is a plan view of another layer of the display module of FIG. 6A according to one or more embodiments;

FIG. 6D is a plan view of still another layer of the display module of FIG. 6A according to one or more embodiments;

FIG. 7 is a cross-sectional view of a display panel according to one or more embodiments;

FIG. 8 is a cross-sectional view of a display panel according to one or more other embodiments;

FIG. 9 is an enlarged cross-sectional view of a pad area of a display module according to one or more embodiments;

FIG. 10 is a cross-sectional view of an electronic apparatus according to one or more embodiments;

FIG. 11 is a cross-sectional view of an electronic apparatus according to a comparative embodiment;

FIG. 12 is a plan view of a display module according to one or more other embodiments;

FIG. 13 is a plan view of a display module according to one or more yet other embodiments; and

FIGS. 14A - 14D are cross-sectional views illustrating some processes of a method of manufacturing an electronic apparatus according to one or more embodiments.

### DETAILED DESCRIPTION

The embodiments of the disclosure described herein are non-limiting example embodiments, and thus, the disclosure is not limited thereto and may be construed to include all modifications, equivalents, or replacements included in the spirit and scope of the disclosure.

In the disclosure, it will be understood that when an element (or area, layer, or portion) is referred to as being “on”, “connected to” or “coupled to” another element or layer, it can be directly on, connected or coupled to the other element or layer or intervening elements or layers may be present. Further, when two or more elements (or components, or layers) are described as being “electrically connected,” these two or more elements may be in a state of electrically connected or being configured to be electrically connected when power is supplied to a device including the two or more elements.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature’s relationship to another elements or features as shown in the figures.

As used herein, the term, “and/or” includes any and all combinations of one or more of the associated listed items. For example, an expression “a and/or b” should be understood as including only a, only b and both a and b. As used herein, the expression “at least one of” preceding a list of elements modifies the entire list of the elements and does not modify the individual elements of the list. For example, expressions “at least one of a, b, and c” and “at least one of a, b, or c” should be understood as including only a, only b, only c, both a and b, both a and c, both b and c, or all of a, b, and c.

Meanwhile, in the disclosure, when an element is referred to as being “directly disposed” to another element, there are no intervening elements present between a layer, film region, or substrate and another layer, film, region, or substrate. For example, the term “directly disposed” may mean that two layers or two members are disposed without employing additional adhesive therebetween.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an electronic apparatus of embodiments of the disclosure will be described with reference to accompanying drawings.

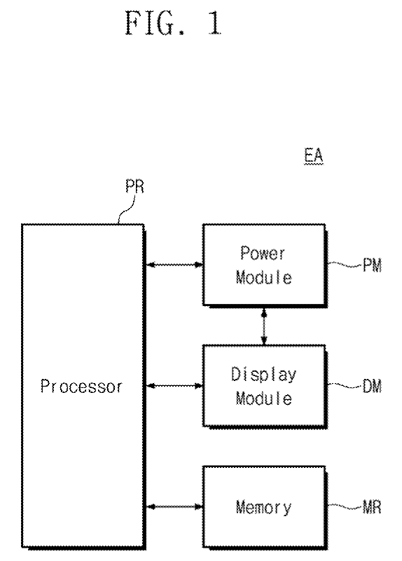

FIG. 1 is a block diagram of an electronic apparatus according to one or more embodiments.

Referring to FIG. 1, the electronic apparatus EA may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), and a controller.

The memory MR may store data information required for operations of at least one of the processor PR and the display module DM. When the processor PR executes an application stored in the memory MR, an image data signal and/or an input control signal may be transmitted to the display module DM, and the display module DM may process the received signals to output image information through a display screen. The display module DM may include a display panel that displays an image.

The power module PM may include a power conversion module. The power conversion module may convert power supplied by a power supply module, such as a power adapter or a battery device, to generate power required for operations of the electronic apparatus EA.

At least one of the components of the electronic apparatus EA may be included in the display module according to embodiments described later and an electronic apparatus according to an embodiment including the display module. In addition, among individual modules that are functionally included within a single module, some may be included in a display device while others may be provided separately from the display device. As an example, the display device may include the display module DM, and the processor PR, the memory MR, and the power module PM may be provided as separate devices within the electronic apparatus EA, rather than being included in the display device.

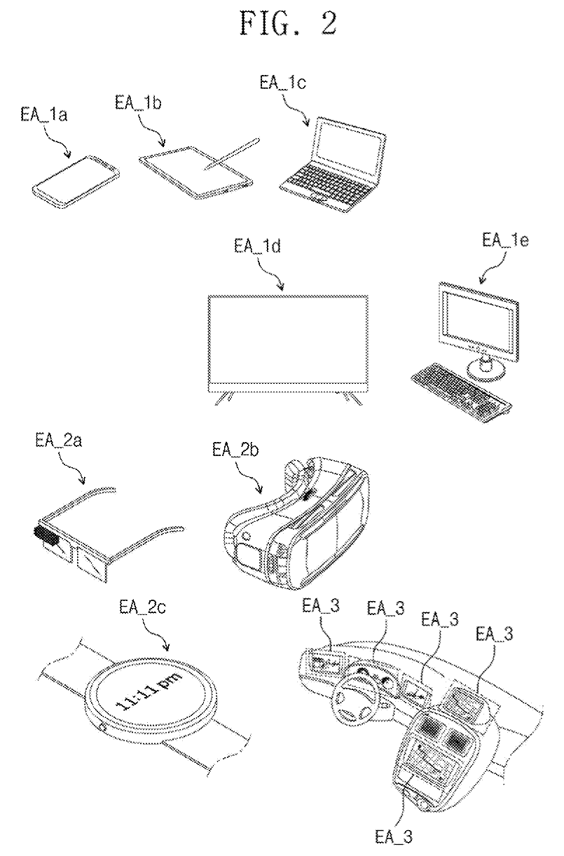

FIG. 2 is a schematic view of electronic apparatuses according to one or more embodiments.

Referring to FIG. 2, various electronic apparatuses to which the display module is applied may include not only an electronic apparatus for displaying images, such as a smartphone EA_1a, a tablet PC EA_1b, a laptop computer EA_1c, a television EA_1d, a desktop monitor EA_1e, etc., but also a wearable electronic apparatus, such as a smart glasses EA_2a, a head-mounted display EA_2b, a smartwatch EA_2c, etc., and an in-vehicle electronic apparatus EA_3, such as an instrument panel, a center fascia, a dashboard-mounted center information display (CID), a room mirror display, etc.

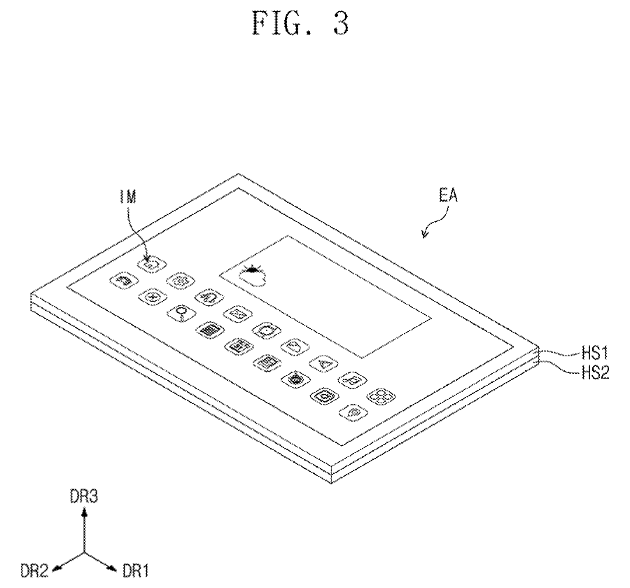

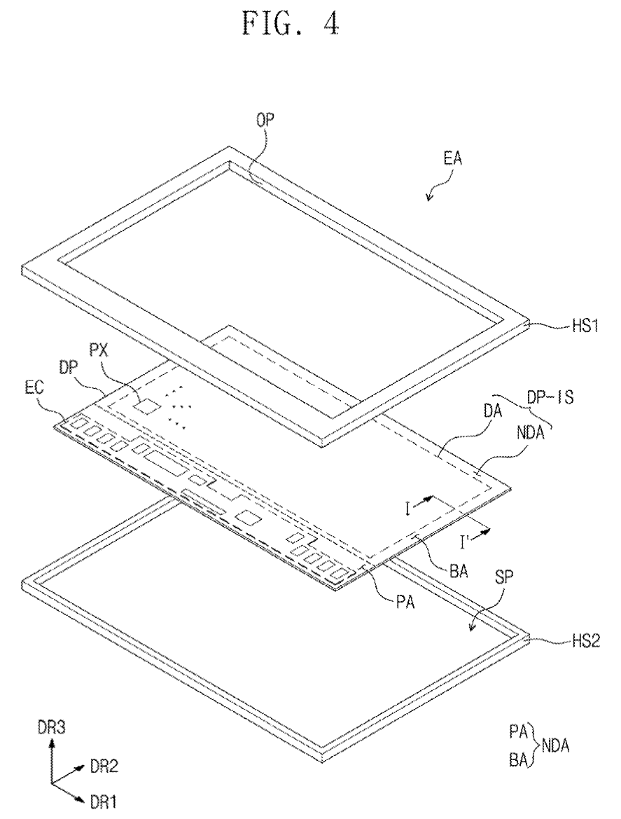

FIG. 3 is a perspective view of the electronic apparatus according to one or more embodiments, and FIG. 4 is an exploded perspective view of the electronic apparatus according to one or more embodiments.

The electronic apparatus EA may provide an image IM to a user. The image IM may include a still image as well as a video. The electronic apparatus EA may include at least one display surface through which the image IM is displayed. The user may obtain information or operate the electronic apparatus EA through the image IM.

The electronic apparatus EA may include the display module DM, an upper cover HS1, and a lower cover HS2. The display module DM may include a display panel DP and an electronic component EC electrically connected to the display panel DP.

The display panel DP may provide a front surface DP-IS, and the front surface DP-IS may include a display area DA and a non-display area NDA.

The display area DA may be an area where the image IM is substantially displayed, and the non-display area NDA may be an area where the image IM is not displayed. A pixel PX may be arranged in the display area DA. The pixel PX may be provided in plural. The pixels PX may display light. The light displayed by the pixels PX may form the image IM.

Each pixel PX may include a display element and a driving element. The display element may be implemented in various embodiments. For example, the display element may be at least one of a liquid crystal capacitor, an organic light emitting device, an electrophoretic device, and an electrowetting device. However, these are merely examples, and the display element may not be limited to the aforementioned embodiments as long as the display element displays an image according to an electrical signal. The driving element may control driving of each of the display elements of each pixel PX. The driving element may include a thin film transistor. The display panel DP may be driven by an active method that allows for independent control of each pixel PX according to one or more embodiments.

The non-display area NDA may be an area adjacent to the display area DA. In the present embodiments, the non-display area NDA is illustrated as having a frame shape surrounding an edge of the display area DA, but the shape of the non-display area NDA in plan view should not be limited thereto or thereby. Signal lines connected to the pixels PX may be arranged in the non-display area NDA. The non-display area NDA may include an edge area BA and a pad area PA. In the present embodiments, the edge area BA may have a frame shape surrounding the display area DA. However, this is merely an example, and the edge area BA may have different shapes as long as the edge area BA is disposed adjacent to the display area DA, and the disclosure should not be limited thereto or thereby.

The electronic component EC may be mounted on the display panel DP. The electronic component EC may be provided in plural, and the electronic components EC may be disposed in the pad area PA in the non-display area NDA and may be spaced apart from each other. The electronic component EC may include various electronic elements necessary for driving the display panel, such as the processor, the power module, and the memory shown in FIG. 1.

The electronic component EC may include active devices and passive devices. For example, the electronic component EC may include chip-related components, network-related components, and other components.

The chip-related component may include at least one of a memory, a processor, and a logic circuit. For example, the memory may include a volatile memory, a non-volatile memory, a flash memory, etc. As an example, the processor may include an application processor, such as a graphics processing unit (GPU), a central processing unit (CPU), a digital signal processor, an encryption processor, a microprocessor, a microcontroller, etc. Furthermore, for example, the logic circuit may include a non-memory semiconductor such as an analog-to-digital converter (ADC), an application specific integrated circuit (ASIC), etc. The chip-related component may be provided in a chip form or a package form.

The network-related components may comply with a wireless protocol and/or a wired protocol. Other components may include an inductor, an electromagnetic interference (EMI) filter, etc.

The upper cover HS1 may be disposed on the display panel DP to protect the display panel DP. The upper cover HS1 may provide an opening OP through which at least a portion of the front surface DP-IS is exposed. The opening OP may be formed with a size corresponding to at least the display area DA. The opening OP may overlap the display area DA, and the image IM displayed through the display area DA may be viewed from the outside through the opening OP.

The lower cover HS2 may be disposed under the display panel DP to protect the display panel DP. The lower cover HS2 may provide an accommodation space SP, and the display panel DP may be accommodated in the accommodation space SP. The lower cover HS2 may be coupled with the upper cover HS1 to form an exterior of the electronic apparatus EA. However, this is merely an example, and the electronic apparatus EA may further include a power supply device such as a battery, other electronic components, or an additional protective member enclosing the upper cover HS1 and the lower cover HS2, and the disclosure may not be limited thereto or thereby.

According to one or more embodiments, the electronic component EC may be disposed directly on the display panel DP and accommodated in the accommodation space SP without a separate circuit board. Accordingly, the use of a conventional flexible printed circuit board (FPCB) or printed circuit board (PCB) may be omitted, so there is no need to secure additional area for the circuit board, and a manufacturing cost may be reduced. In addition, the electronic component EC may be accommodated in the accommodation space SP without being folded, and the display panel DP and the electronic component EC may be assembled in a state substantially parallel to a plane defined by a first direction DR1 and a second direction DR2 that are horizontal directions crossing each other. Therefore, an increase in the thickness of the electronic apparatus, which occurs due to the placement of the circuit board, may be prevented, and a thinner and more highly integrated structure may be implemented.

However, the disclosure may not be limited thereto or thereby, and some of the electronic components EC may be mounted on the display panel DP, while the remaining of the electronic components EC may be mounted on a flexible printed circuit board or a printed circuit board. For example, the arrangement of the electronic components may be different depending on functions and wiring structures.

According to one or more embodiments, as the circuit board is omitted, a separate folding area for a folding operation may not be provided, and thus, a separate flexible film or additional wiring structure to connect the circuit board to the display panel DP may be unnecessary. Accordingly, the number of components may be reduced, the manufacturing cost may be lowered, the assembly process may be simplified, and the structural stability of the electronic apparatus may be improved. However, the disclosure may not be limited thereto or thereby, and according to one or more embodiments, a display module of the electronic apparatus EA may include the circuit board. Detailed descriptions thereof will be provided later.

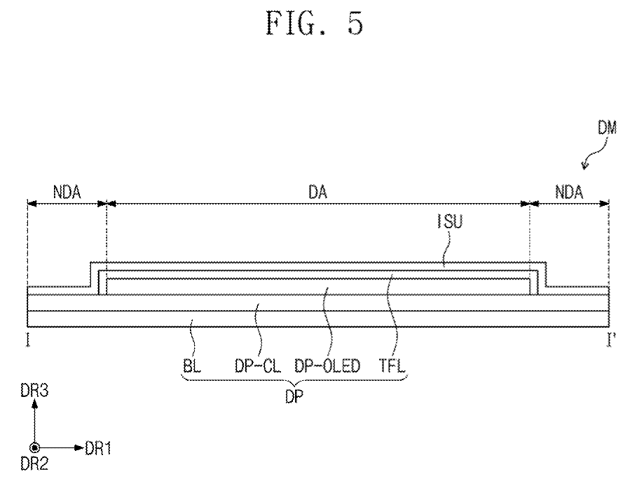

FIG. 5 is a cross-sectional view of a display module taken along a line I-I’ of FIG. 4 according to one or more embodiments.

Referring to FIG. 5, a display panel DP may include a substrate BL, a circuit element layer DP-CL, a display element layer DP-OLED, and an encapsulation layer TFL, which are sequentially stacked on the substrate BL. An input sensor ISU may be disposed on the encapsulation layer TFL. The display panel DP shown in FIG. 5 may be the same as or similar to the display panel DP shown in FIG. 4.

The display panel DP may include a display area DA and a non-display area NDA. The display area DA of the display panel DP may correspond to the display area DA shown in FIG. 4, and the non-display area NDA may correspond to the non-display area NDA shown in FIG. 4.

The substrate BL may include at least one plastic film. The substrate BL may be a flexible substrate and may include a plastic substrate, a glass substrate, a metal substrate, or an organic/inorganic composite material substrate.

The circuit element layer DP-CL may include at least one intermediate insulating layer and at least one circuit element. The intermediate insulating layer may include at least one intermediate inorganic layer and at least one intermediate organic layer. The at least one circuit element may include signal lines and a pixel driving circuit.

The display element layer DP-OLED may include a plurality of organic light emitting diodes. The display element layer DP-OLED may further include an organic layer such as a pixel definition layer.

The encapsulation layer TFL may encapsulate the display element layer DP-OLED. The encapsulation layer TFL may be disposed on the display element layer DP-OLED. The encapsulation layer TFL may overlap the display area DA and the non-display area NDA. The encapsulation layer TFL may overlap at least a portion of the non-display area NDA. The encapsulation layer TFL may have a stack structure of an inorganic layer/organic layer/inorganic layer. The encapsulation layer TFL may protect the display element layer DP-OLED from moisture, oxygen, and a foreign substance such as dust particles.

According to one or more embodiments, a sealing substrate may be provided instead of the encapsulation layer TFL. In this case, the sealing substrate may be opposite to the substrate BL, and the circuit element layer DP-CL and the display element layer DP-OLED may be disposed between the sealing substrate and the substrate BL.

The input sensor ISU may be disposed directly on the display panel DP. In the disclosure, the expression “component A is disposed directly on component B” means that no intervening elements are present between the component A and the component B. In the present embodiments, the input sensor ISU may be formed through a continuous process with the display panel DP, however, the disclosure may not be limited thereto or thereby. According to one or more embodiments, the input sensor ISU may be provided as an individual panel and then may be coupled to the display panel DP by an adhesive layer. According to one or more embodiments, the input sensor ISU may be omitted.

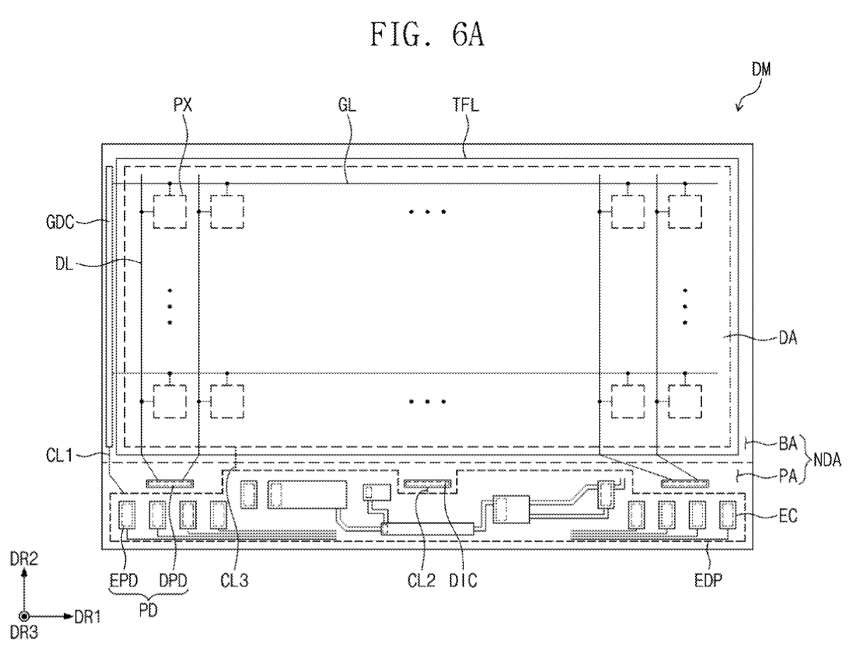

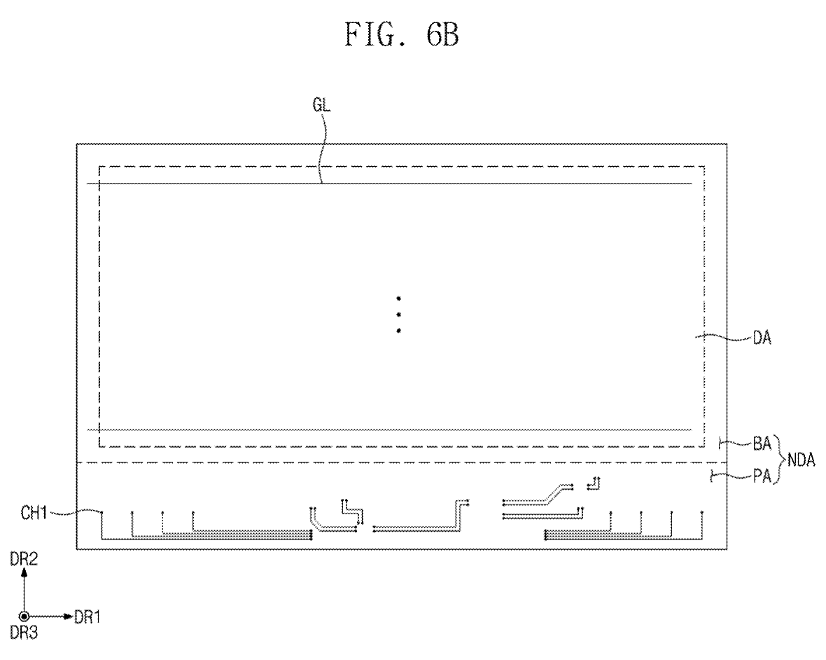

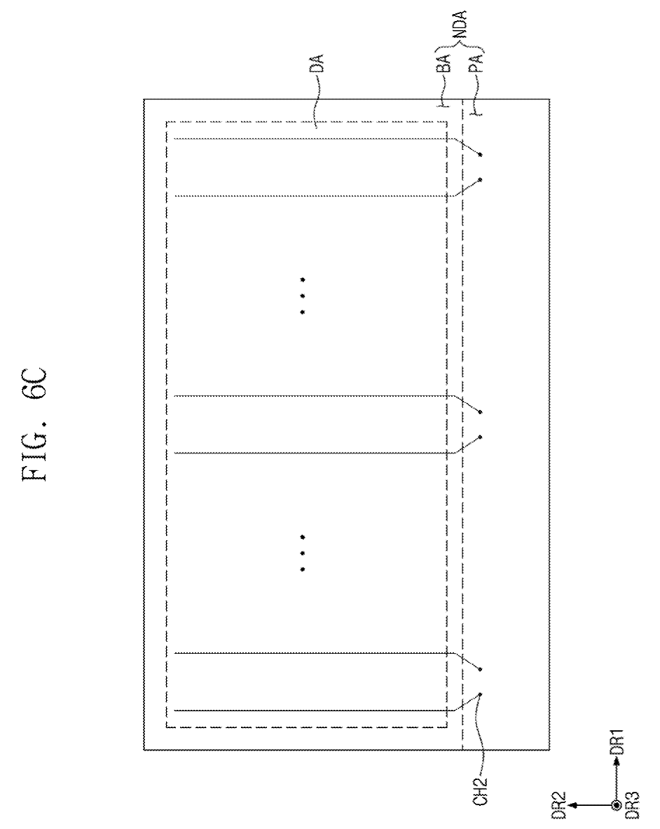

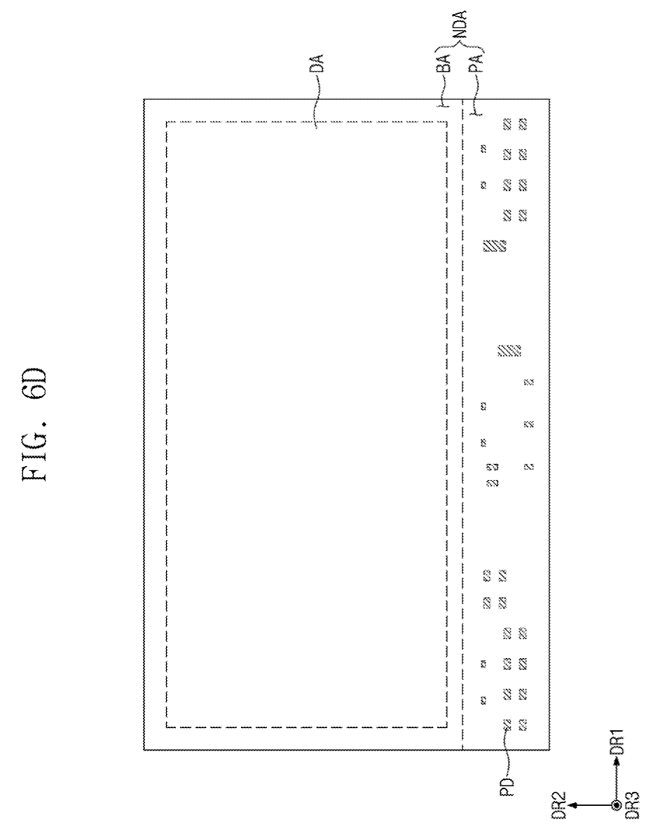

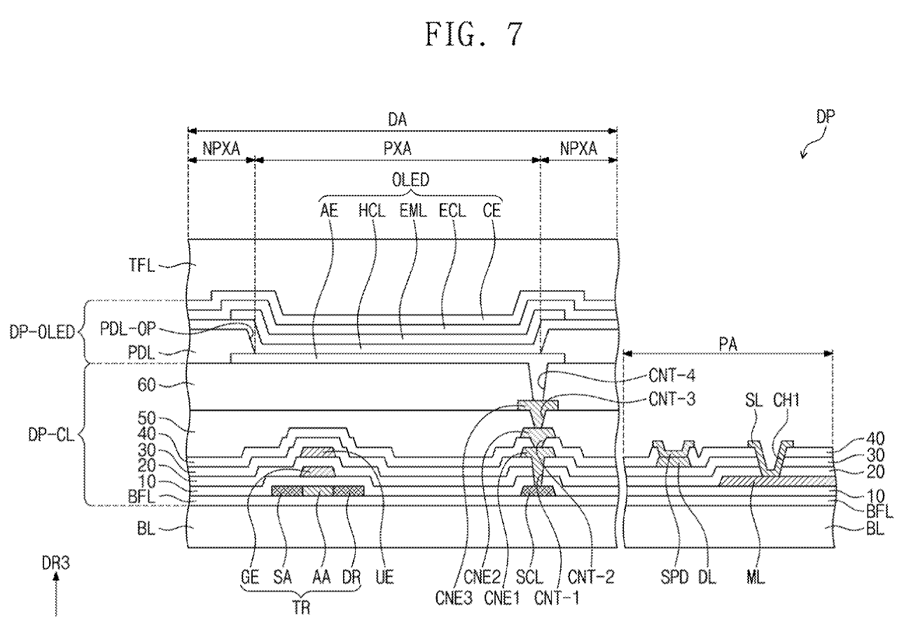

FIG. 6A is a plan view of a display module according to one or more embodiments. FIG. 6B is a plan view of a layer of the display module of FIG. 6A according to one or more embodiments. FIG. 6C is a plan view of another layer of the display module of FIG. 6A according to one or more embodiments. FIG. 6D is a plan view of still another layer of the display module of FIG. 6A according to one or more embodiments. FIG. 7 is a cross-sectional view of a display panel according to one or more embodiments.

A display module DM shown in FIG. 6A may include a display panel DP and an electronic component EC. The display module DM, the display panel DP and the electronic component EC may be the same as or similar to the corresponding elements described above in reference to FIGS. 1-5

The display panel DP may include a display area DA and a non-display area NDA in plan view. As described above, the display area DA may be the area where images are displayed. Pixels PX that implement the images may be arranged in the display area DA. Components of the pixels PX, which generate or display light, may be arranged in the display area DA. The pixels PX may be arranged in a matrix shape along the second direction DR2 and the first direction DR1. The display panel DP may control the pixels PX to display images.

The non-display area NDA may be adjacent to the display area DA. Signal lines connected to the pixels PX may be arranged in the non-display area NDA. As an example, a gate driver GDC, a component driver EDP, and a driving chip DIC may be disposed in the non-display area NDA. Gate lines GL may extend in the first direction DR1 and arranged in the second direction DR2, and may be connected to the gate driver GDC. Data lines DL may extend in the second direction DR2 and arranged in the first direction DR1, and may be connected to the driving chip DIC. A first connection line CL1 may connect the component driver EDP and the gate driver GDC. A second connection line CL2 may connect the component driver EDP and the driving chip DIC. A connection line CL3 may connect the component driver EDP and the display element layer DP-OLED (refer to FIG. 7).

The gate driver GDC may receive a gate control signal from a timing controller included in the component driver EDP via the first connection line CL1. The gate driver GDC may output gate signals to the gate lines GL in response to the gate control signal. The gate signals may be applied to the pixels PX via the gate lines GL.

The driving chip DIC may receive a control signal and an image data signal via the second connection line CL2 from the timing controller included in the component driver EDP. The driving chip DIC may convert the image data signal into data signals and output the data signals. The data signals may be implemented by analog voltages corresponding to grayscale levels of the image data signal. The data signals may be applied to the pixels PX via the data lines DL.

The pixel PX may be connected to the third connection line CL3 connected to a voltage generator and may receive a first initialization voltage, a second initialization voltage, a reference voltage, a first driving voltage, and a second driving voltage.

The non-display area NDA may include an edge area BA and a pad area PA. In the present embodiments, the edge area BA may have a frame shape surrounding the display area DA, however, this is merely an example. The edge area BA may have different shapes as long as the edge area BA is adjacent to the display area DA, and the disclosure may not be particularly limited.

The pad area PA may be spaced apart from the display area DA and may be adjacent to the edge area BA. In the present embodiments, the pad area PA is shown as being spaced apart from the display area DA in the second direction DR2, however, the disclosure may not be limited thereto or thereby. The pad area PA may be spaced apart from the display area DA in the first direction DR1 or may be spaced apart from the display area DA in the second direction DR2 and the area spaced apart from the display area DA in the first direction DR1, but it may not be particularly limited thereto.

A plurality of display pad parts PD may be arranged in the pad area PA of the display panel DP. The display pad parts PD may be spaced apart from each other with a selected distance. At least one display pad may be arranged in each of the display pad parts PD. The display pad parts PD may include a chip pad part DPD electrically connected to the driving chip DIC and a component pad part EPD including component pads electrically connected to the electronic component EC. The driving chip DIC and the electronic component EC may be disposed on the display pad part PD and may be electrically connected to the display panel DP.

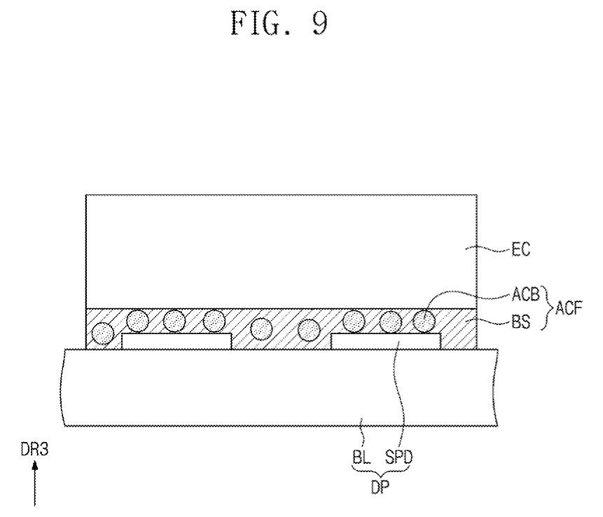

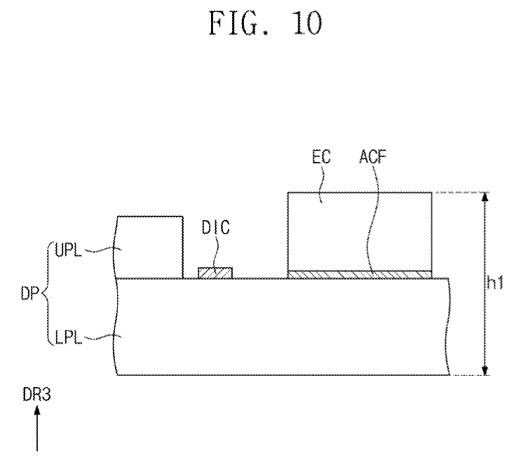

The electronic component EC may be disposed in the pad area PA. The electronic component EC may be spaced apart from the encapsulation layer TFL in plan view. The electronic component EC may be electrically connected to the circuit element layer DP-CL (refer to FIG. 5) of the display panel DP through a connection member ACF (refer to FIG. 9). In detail, the electronic component EC may be connected to a wiring layer ML (referring to FIG. 7) disposed on the circuit element layer DP-CL of the display panel DP.

The display module DM may further include the driving chip DIC arranged on the display panel DP. The driving chip DIC may include driving elements, for example, the data driver, to drive the pixels of the display panel DP. However, the disclosure may not be limited thereto or thereby. According to one or more embodiments, in a case where the display module DM includes a circuit board, the driving chip DIC may be mounted on the circuit board.

According to one or more embodiments, as described above, the electronic component EC may be connected to the wiring layer ML disposed in the circuit element layer DP-CL of the display panel DP. Accordingly, a conventional flexible printed circuit board or printed circuit board may be omitted, and the electronic component EC may be directly mounted on the display panel DP without a separate circuit board. Accordingly, additional components, such as separate flexible films or wiring films, to connect the display panel DP and the electronic component EC are not needed, and thus, a process cost may be reduced, and an assembly process may be simplified. However, the disclosure may not be limited thereto or thereby. According to one or more embodiments, some of the electronic components EC may be mounted on the display panel DP, and the others may be mounted on the circuit board. Detailed descriptions thereof will be described later.

FIG. 6B is a plan view showing a layer where a gate of a transistor TR (refer to FIG. 7) is disposed. FIG. 6C is a plan view showing a layer where a first connection electrode CNE1 is disposed, and FIG. 6D is a plan view showing a layer where a second connection electrode CNE2 is disposed.

Referring to FIG. 6B, the gate line GL and the wiring layer ML may be arranged at a same layer on which a gate electrode GE of the transistor TR is disposed. For example, the gate line GL and the wiring layer ML may be formed through a same process as the gate electrode GE of the transistor TR and may include a same material as the gate electrode GE, thereby simplifying at least a manufacturing process.

The wiring layer ML may be disposed in the pad area PA and may be spaced apart from the gate line GL in plan view.

The wiring layer ML may be connected to a pad SL (refer to FIG. 7) via a contact hole CH1 (or opening) formed through a plurality of insulating layers stacked on the wiring layer ML.

Referring to FIGS. 6C and 6D, the data line DL may be disposed on a layer on which the first connection electrode CNE1 is disposed, and the display pads and the pad SL, which are disposed in the display pad part PD, may be disposed on a layer on which the second connection electrode CNE2 is disposed. The data line DL may be formed through a same process as the first connection electrode CNE1 and may include a same material as the first connection electrode CNE1. The display pads and the pad SL may be formed through a same process as the second connection electrode CNE2 and may include a same material as the second connection electrode CNE2.

The data line DL may extend from the display area DA to the pad area PA. The data line DL may be connected to the display pad disposed in the display pad part PD via a contact hole CH2 formed through a plurality of insulating layers stacked on the data line DL.

Referring to FIG. 7, a display area DA of a display panel DP may include a light emitting area PXA and a non-light-emitting area NPXA. The display pane DP may be the same as or similar to the display panel DP described above in reference to FIGS. 1 - 6A-6D. Each of the pixels PX (refer to FIG. 6A) may include an organic light emitting diode OLED and a pixel driving circuit, also referred to as a pixel driver, connected to the organic light emitting diode OLED. For example, the pixel PX may include a transistor TR and a light emitting element OLED. The light emitting area PXA may be an area from which light emitted from the light emitting element OLED exits.

The display panel DP may include a substrate BL, a circuit element layer DP-CL, a display element layer DP-OLED, and an encapsulation layer TFL.

As an example, FIG. 7 shows one transistor TR, however, the disclosure may not be limited thereto or thereby. A pixel driver of the pixel PX may include seven transistors and at least one capacitor, and the seven transistors and the capacitor may be electrically connected to each other. However, the number of the transistors and the number of the capacitors, which constitute the pixel PX, may not be particularly limited thereto.

The display panel DP may include a plurality of insulating layers, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned by photolithography and etching processes. Thus, the semiconductor pattern, the conductive pattern, and the signal line included in the circuit element layer DP-CL and the display element layer DP-OLED may be formed.

The substrate BL may include a glass substrate, a sapphire substrate, a plastic film, or an organic/inorganic stacked-film. The substrate BL may have a single-layer or multi-layer structure. As an example, the substrate BL may include a stack structure of a plurality of plastic films attached to each other by an adhesive or a stack structure of a glass substrate and a plastic film attached to the glass substrate by an adhesive. The substrate BL may have flexibility. As an example, the substrate BL may include polyimide (PI), however, this is merely an example. According to an embodiment, the substrate BL may be a rigid substrate, but it should not be particularly limited.

The circuit element layer DP-CL may be disposed on the substrate BL. The circuit element layer DP-CL may include the pixel driver, a component driver, a buffer layer BFL, and a plurality of insulating layers 10, 20, 30, 40, 50, and 60. The pixel driver may include a circuit to drive the pixel PX, and the component driver may include a circuit to drive an electronic component.

The buffer layer BFL may enhance an adhesion between the substrate BL and the semiconductor pattern. The buffer layer BFL may include a silicon oxide layer and/or a silicon nitride layer. In the case where the buffer layer BFL includes the silicon oxide layer and the silicon nitride layer, the silicon oxide layer and the silicon nitride layer may be alternately stacked with each other.

The semiconductor pattern may be disposed on the buffer layer BFL. The semiconductor pattern may include polycrystalline silicon, however, the disclosure may not be limited thereto or thereby. According to one or more embodiments, the semiconductor pattern may include amorphous silicon or metal oxide.

FIG. 7 only illustrates a portion of the semiconductor patterns, and at least one semiconductor pattern may further be arranged in a plurality of light emitting areas PXA.

The semiconductor pattern may include a plurality of regions distinguished from each other according to conductivity. The semiconductor pattern may include a source area SA, a channel area AA, and a drain area DR. The channel area AA may have a relatively low electrical conductivity compared to the source area SA and the drain area DR. The source area SA and the drain area DR may be spaced apart from each other, and the channel area AA may be disposed between the source area SA and the drain area DR. The channel area AA of the semiconductor pattern may be formed to correspond to a gate electrode GE.

In the present embodiments, the transistor TR may have a top-gate structure, however, this is merely an example. According to an embodiment, the gate electrode GE may be disposed under the semiconductor pattern and may not be particularly limited.

FIG. 7 shows a portion of a connection signal line SCL formed from the semiconductor pattern. In one or more embodiments, the connection signal line SCL may be electrically connected to a drain of one of the transistors arranged in the pixel PX.

A first insulating layer 10 may be disposed on the buffer layer BFL. The first insulating layer 10 may cover at least a portion of the semiconductor pattern. The first insulating layer 10 may commonly overlap the pixels PX, for example, in the third direction DR3. The gate electrode GE may be disposed on the first insulating layer 10. The gate electrode GE may be a part of a metal pattern. The gate electrode GE may overlap the channel area AA, for example, in the third direction DR3. The gate electrode GE may function as a mask in a process of doping the semiconductor pattern.

A second insulating layer 20 may be disposed on the first insulating layer 10 to cover at least a portion of the gate electrode GE. The second insulating layer 20 may commonly overlap the pixels PX, for example, in the third direction DR3. An upper electrode UE may be disposed on the second insulating layer 20. The upper electrode UE may overlap the gate electrode GE of the transistor TR, for example, in the third direction DR3. The upper electrode UE may be a part of a metal pattern. A portion of the gate electrode GE and the upper electrode UE overlapping the portion of the gate electrode GE may form a capacitor.

A third insulating layer 30 may be disposed on the second insulating layer 20 to cover at least a portion of the upper electrode UE. The first connection electrode CNE1 disposed on the third insulating layer 30 may be connected to the connection signal line SCL via a contact hole CNT-1 formed through the first, second, and third insulating layers 10, 20, and 30.

A fourth insulating layer 40 may be disposed on the third insulating layer 30 to cover at least a portion of the first connection electrode CNE1. A second connection electrode CNE2 may be disposed on the fourth insulating layer 40. The second connection electrode CNE2 may be connected to the first connection electrode CNE1 via a contact hole CNT-2 formed through the fourth insulating layer 40.

The first, second, third, and fourth insulating layers 10, 20, 30, and 40 may be an inorganic layer and/or an organic layer and may have a single-layer or multi-layer structure.

A fifth insulating layer 50 may be disposed on the fourth insulating layer 40. The fifth insulating layer 50 may be an organic layer. A third connection electrode CNE3 may be disposed on the fifth insulating layer 50. The third connection electrode CNE3 may be connected to the second connection electrode CNE2 via a contact hole CNT-3 formed through the fifth insulating layer 50.

A sixth insulating layer 60 may be disposed on the fifth insulating layer 50 to cover at least a portion of the third connection electrode CNE3. The sixth insulating layer 60 may be an organic layer. A first electrode AE may be disposed on the sixth insulating layer 60. The first electrode AE may be connected to the third connection electrode CNE3 via a contact hole CNT-4 formed through the sixth insulating layer 60.

A light emitting opening PDL-OP may be formed through a pixel definition layer PDL. At least a portion of the first electrode AE may be exposed through the light emitting opening PDL-OP of the pixel definition layer PDL. In the present embodiments, the light emitting area PXA may be formed to correspond to a portion of the first electrode AE exposed through the light emitting opening PDL-OP.

A hole control layer HCL may be commonly disposed in the light emitting area PXA and the non-light-emitting area NPXA. The hole control layer HCL may include a hole transport layer and may further include a hole injection layer. A light emitting layer EML may be disposed on the hole control layer HCL. The light emitting layer EML may be disposed in an area corresponding to the light emitting opening PDL-OP. For example, the light emitting layer EML may be formed separately for each of the pixels PX, however, the disclosure may not be limited thereto or thereby. In one or more embodiments, the light emitting layer EML may be commonly formed in the pixels PX using an open mask.

An electron control layer ECL may be disposed on the light emitting layer EML. The electron control layer ECL may include an electron transport layer and may further include an electron injection layer. The hole control layer HCL and the electron control layer ECL may be commonly formed in the pixels PX using an open mask. A second electrode CE may be disposed on the electron control layer ECL. The second electrode CE may have an integral shape and may be commonly disposed across the pixels PX. The encapsulation layer TFL may be disposed on the second electrode CE. The encapsulation layer TFL may include a plurality of inorganic thin layers and/or an organic thin layer.

In the present embodiments, a component driver EDP may be disposed in a pad area PA. The component driver may include a portion of a data line DL, a display pad SPD, a wiring layer ML, and a pad SL.

In the pad area PA, a portion of the data line DL may be disposed on the first insulating layer 10. The other portion of the data line DL may be disposed on the fifth insulating layer 50 in the display area DA. The data line DL may extend from the display area DA to the pad area PA, and the data line DL may include a plurality of portions disposed at different layers depending on the area.

The display pad SPD may be disposed in the pad area PA. The display pad SPD may be one of the display pads arranged in the display pad part PD shown in FIG. 6A. The display pad SPD may be connected to a portion of the data line DL, for example, an end portion, via a contact hole formed through the second insulating layer 20 to the fourth insulating layer 40.

The wiring layer ML may be disposed in the pad area PA. The wiring layer ML may be disposed on the first insulating layer 10. The wiring layer ML may be disposed at a same layer as the gate electrode GE of the transistor TR. For example, the wiring layer ML may be formed through a same process as the gate electrode GE.

The pad SL may be disposed on the wiring layer ML. The pad SL may be disposed at a same layer as the second connection electrode CNE2. The pad SL may be disposed on the wiring layer ML and may electrically connect the wiring layer ML and an electronic component EC. The pad SL may be connected to the wiring layer ML via the contact hole CH1 formed through the second insulating layer 20 to the fourth insulating layer 40. The pad SL may include at least one of titanium (Ti), aluminum (Al), and molybdenum (Mo).

The buffer layer BFL and the first, second, third, and fourth insulating layers 10, 20, 30, and 40 may be disposed also in the pad area PA. For example, portions of the insulating layers 10, 20, 30, 40, 50, and 60 constituting the circuit element layer DP-CL may be included in the pad area PA, and a stacked structure of the insulating layers in the pad area PA may not be particularly limited thereto.

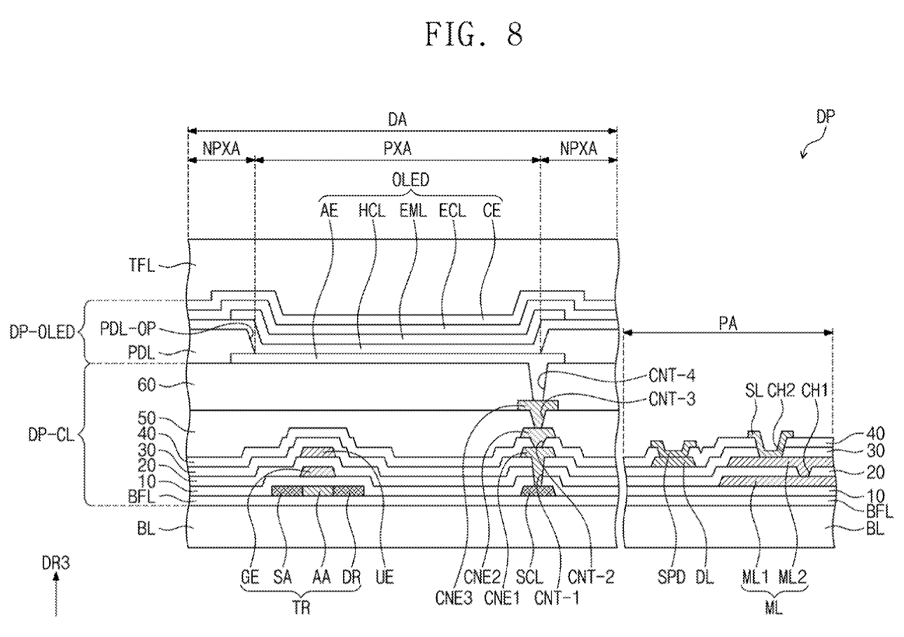

FIG. 8 is a cross-sectional view of a display panel according to one or more other embodiments. A display panel DP shown in FIG. 8 may be the same as or similar to the display panel PA described above in reference to FIGS. 1 - 6A-6D.

Referring to FIG. 8, a wiring layer ML may include a plurality of layers. In detail, the wiring layer ML may include a first wiring layer ML1 and a second wiring layer ML2. The first wiring layer ML1 may be disposed on a first insulating layer 10. The second wiring layer ML2 may be disposed on the first wiring layer ML1.

A pad SL may be disposed on the second wiring layer ML2. The pad SL may be disposed at a same layer as a second connection electrode CNE2. The pad SL may be disposed on the wiring layer ML and may electrically connect the wiring layer ML and an electronic component EC (refer to FIG. 6A).

The second wiring layer ML2 may be connected to the first wiring layer ML1 via a contact hole CH1 formed through a second insulating layer 20. The pad SL may be connected to the second wiring layer ML2 via a contact hole formed through third and fourth insulating layers 30 and 40. For example, the first wiring layer ML1, the second wiring layer ML2, and the pad SL may be connected to each other through one or more insulating layers.

In the present embodiments, a multi-layer wiring structure for signal transmission may be formed in an area where the electronic component EC is disposed. Compared to a single-layer wiring structure, the multi-layer wiring structure may lead to improvement in wiring density in a same area, and thus, the multi-layer wiring structure may improve a signal transmission efficiency between electronic components EC and may be advantageous for driving high-resolution panels. In addition, as the wiring may be distributed between layers within a limited area, it may be advantageous in terms of space utilization.

FIG. 9 is an enlarged cross-sectional view of a pad area of a display module according to one or more embodiments. FIG. 9 shows a structure in which an electronic component EC and a display panel DP are attached to each other by a connection member ACF. The electronic component EC of FIG. 9 may correspond to the electronic component EC of FIG. 4, and display pads SPD of FIG. 9 may correspond to a portion of the display pads arranged in the display pad part PD of FIG. 6A.

The electronic component EC may include bump electrodes, and each of the bump electrodes may be electrically connected to a corresponding display pad of the display pads SPD by the connection member ACF. In this case, the connection member ACF may include a solder.

The bump electrodes may be electrically connected to the display pads SPD by conductive balls ACB. Accordingly, the electronic component EC may be electrically connected to the display panel DP.

In one or more embodiments, when the electronic component EC and the display panel DP are disposed adjacent to the connection member ACF, a near-infrared laser may be irradiated from below a substrate BL in a third direction DR3. Accordingly, a resin component of the connection member ACF may be cured, and the solder of the connection member ACF may be melted. Then, as the connection member ACF is cured and the solder is melted and solidified, the electronic component EC and the display panel DP may be electrically and mechanically connected to each other. Detailed descriptions thereof will be provided later.

For the convenience of explanation, the display pads SPD are illustrated as being directly disposed on the substrate BL in FIG. 9, but at least one insulating layer may be further disposed between the display pads SPD and the substrate BL.

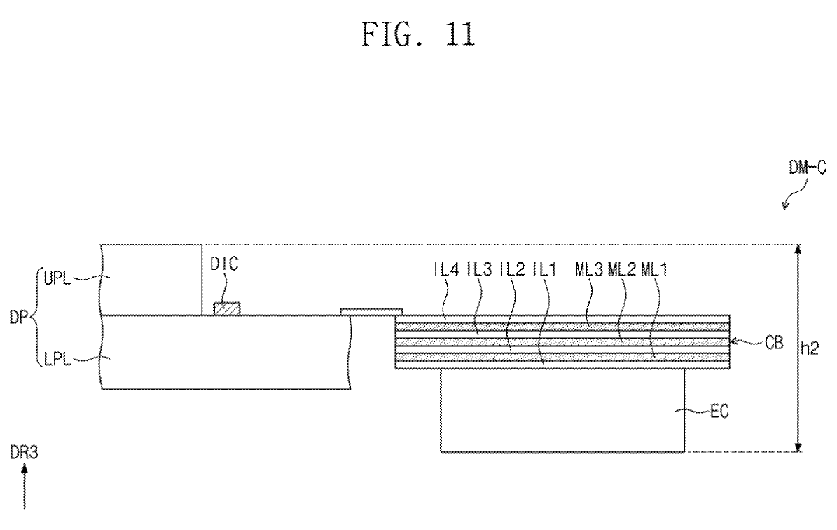

FIG. 10 is a cross-sectional view of an electronic apparatus according to one or more embodiments. FIG. 11 is a cross-sectional view of an electronic apparatus according to a comparative embodiment. In FIGS. 10 and 11, the same/similar reference numerals denote the same/similar elements in FIGS. 6A - 6D and 7 - 9, and thus, detailed descriptions of the same element will be omitted.

A display module DM shown in FIG. 10 may substantially correspond to the display panel DP shown in FIG. 7. Therefore, the same descriptions as given with FIG. 7 will be omitted.

Referring to FIG. 10, the display panel DP may include a lower substrate LPL and an upper substrate UPL disposed on the lower substrate LPL. In this case, the lower substrate LPL may correspond to the substrate BL and a portion of the circuit element layer DP-CL of FIG. 7, and the upper substrate UPL may correspond to the other portion of the circuit element layer DP-CL, the display element layer DP-OLED, and the encapsulation layer TFL of FIG. 7.

Referring to FIG. 11, a display module DM-C according to the comparative example may include a display panel DP, a circuit board CB, and an electronic component EC. For example, in the comparative example, the display module DM-C has a structure that further includes the circuit board CB on which the electronic component EC is mounted, and thus, a thickness of the display module DM-C may increase.

The circuit board CB may be electrically connected to a display pad part PD (refer to FIG. 6A) disposed in a pad area PA (refer to FIG. 6A) via a film. The circuit board CB may provide image data, a control signal, a power voltage, and the like to the display panel DP. This is merely an example, and when the display panel DP is configured to sense an external input, such as touch, pen, or light applied from the outside, the circuit board CB may provide a driving signal to sense the external input to the display panel DP.

The circuit board CB may be physically and electrically connected to the display panel DP. For example, the circuit board CB may be physically disposed separate from the display panel DP including the lower substrate LPL and the upper substrate UPL and connected to the display panel in the first direction DR1 or the second direction DR2. The electronic component EC may be mounted on the circuit board CB.

The circuit board CB may be a printed circuit board PCB and may be rigid. The circuit board CB may include at least one insulating layer and at least one wiring layer. FIG. 11 shows the structure in which the circuit board CB includes three wiring layers ML1, ML2, and ML3 and four insulating layers IL1, IL2, IL3, and IL4, however, this is merely an example, and the number of the wiring layers and the number of the insulating layers may not be limited thereto.

In the present embodiments including the embodiment of FIG. 10, the circuit board may be omitted. Accordingly, the electronic component EC may be connected to the wiring layer of the display panel DP. As a result, a total thickness of an electronic apparatus including the display panel DP may be reduced by a thickness occupied by the circuit board, and thus, a space efficiency in manufacturing the electronic apparatus may increase.

Referring to FIGS. 10 and 11, a thickness h1 of the display module DM according to the present embodiments, where the circuit board is omitted, may be smaller than a thickness h2 of the display module DM-C that includes the circuit board CB according to the comparative embodiment. The thickness of the display module may refer to a distance from a lower surface of a component disposed at a lowermost position to an upper surface of a component disposed at an uppermost position of the display module. For example, according to the present disclosure, a separate circuit board for the mounting of the electronic component EC may be omitted, and accordingly, the thickness of the display module may be reduced.

In addition, additional processes to connect the circuit board CB and the display panel DP may become unnecessary, and thus, the manufacturing process may be simplified and the manufacturing cost may be reduced. Further, a border area of the display panel may be reduced, which provides the electronic apparatus having a narrower bezel.

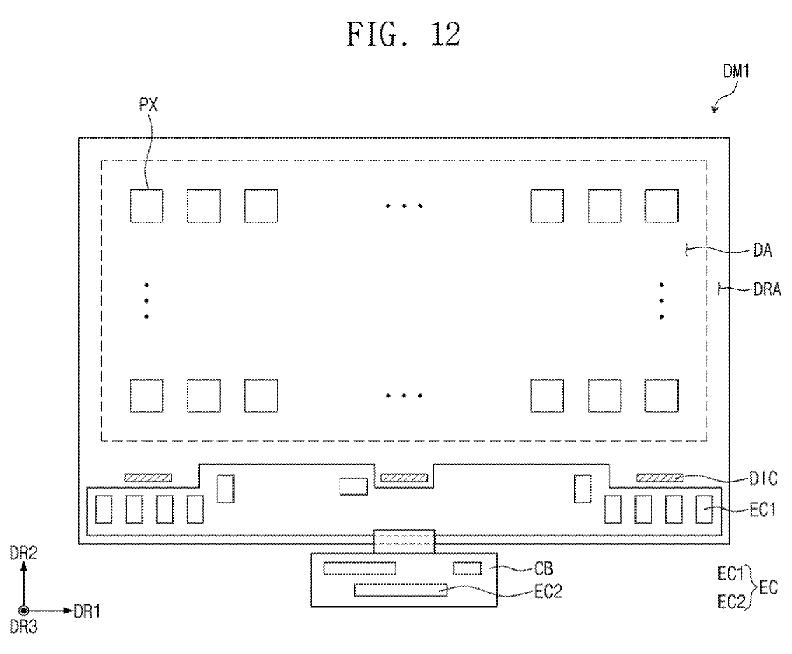

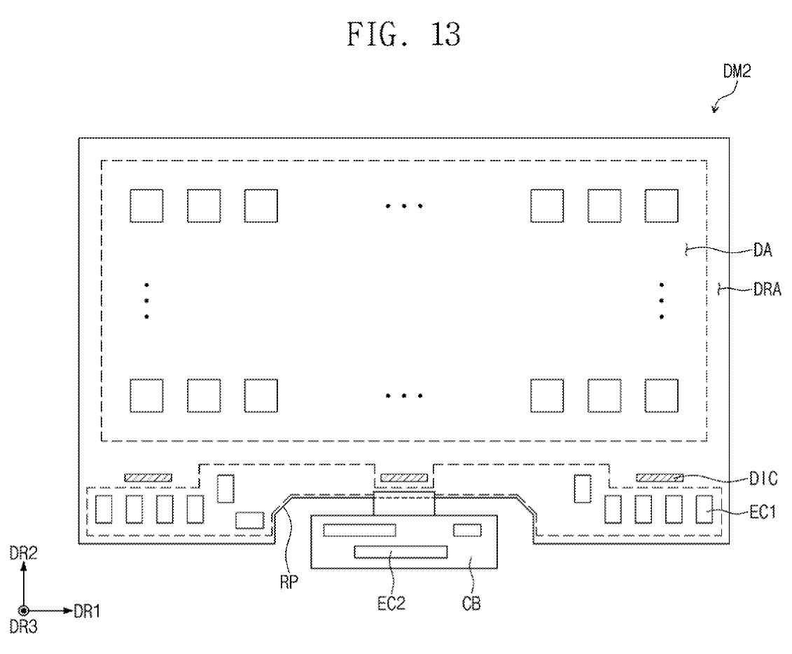

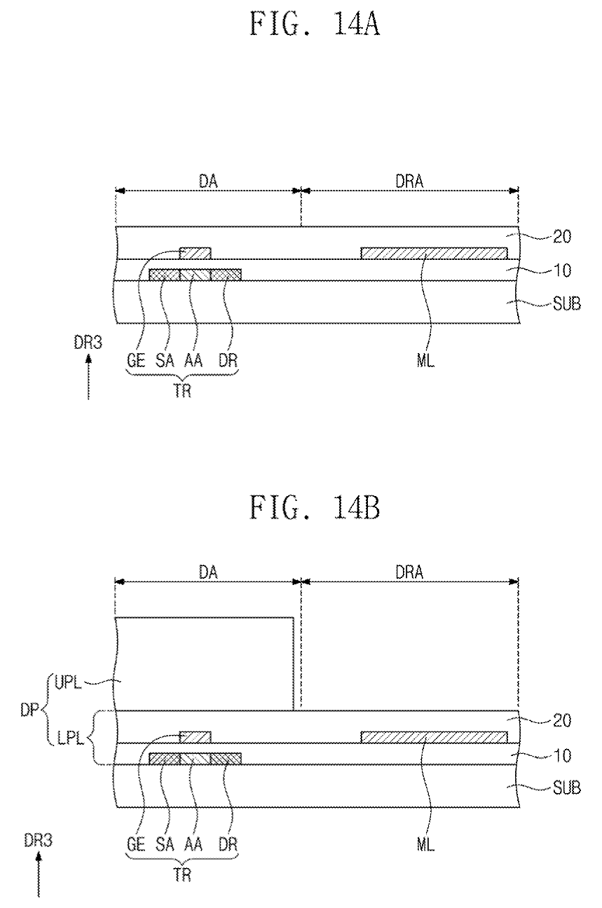

FIG. 12 is a plan view of a display module according to one or more other embodiments. FIG. 13 is a plan view of a display module according to one or more yet other embodiments. In FIGS. 12 and 13, the same/similar reference numerals denote the same/similar elements in FIGS. 6A - 6D and 7 - 11, and thus, detailed descriptions of the same element will be omitted.

Referring to FIG. 12, the display module DM1 may include a display area DA and a driving area DRA. The display area DA may be an area where a pixel PX is disposed, and the driving area DRA may be an area where a driving circuit and a wiring are disposed. The driving area DRA may correspond to the non-display area NDA of FIG. 6a.

The display module DM1 may further include a circuit board CB on which an electronic component EC2 is mounted. As described above, according to the disclosure, the electronic component EC may be connected to a wiring layer ML (refer to FIG. 7) of a display panel DP (refer to FIG. 7), and the circuit board CB may be omitted. However, according to one or more embodiments, only a portion of the electronic components may be connected to the wiring layer ML of the display panel DP and mounted on the display panel DP, and the other electronic components may be mounted on the separated circuit board CB.

As an example, some electronic components, such as a controller IC and a timing control circuit (T-Con) may be mounted on the circuit board CB, and the other electronic components except the controller IC and the timing control circuit (T-Con) may be mounted on the display panel DP. In this case, since at least some of the electronic components are mounted on the display panel DP, the number of the electronic components mounted on the circuit board CB may be reduced, and when compared to a case where all electronic components are mounted on the circuit board, a width, length, and thickness of the circuit board may be reduced.

Referring to FIG. 13, the display module DM2 may include a display area DA and a driving area DRA. The driving area DRA may include a recess portion RP having a concave shape in plan view. The recess portion RP may have a shape formed by processing a portion of a substrate BL of a display panel DP (refer to FIG. 7) . The recess portion RP may be formed by grinding at least one side of the substrate BL. For example, at least one side of the substrate BL may include a curved portion that is concave toward the display area DA. A circuit board may be disposed in the recess portion RP.

As described above, the recess portion RP may be formed by processing the substrate BL of the display panel DP to reduce a border of an electronic apparatus including the display module DM2, and this allows a circuit board CB to be placed within the recess portion RP. Accordingly, an area where the circuit board CB protrudes outside the display panel DP is reduced, and a larger part of the circuit board CB may be placed inside the display panel DP. As a result, a total area of the electronic apparatus may be reduced. Further, as described above, since at least some of the electronic components are mounted on the wiring layer of the display panel DP, the width, length, and thickness of the circuit board CB may be reduced.

The shape formed by processing the substrate BL of the display panel DP may not be limited to a particular structure and may be modified into various shapes as long as the border of the electronic apparatus may be reduced.

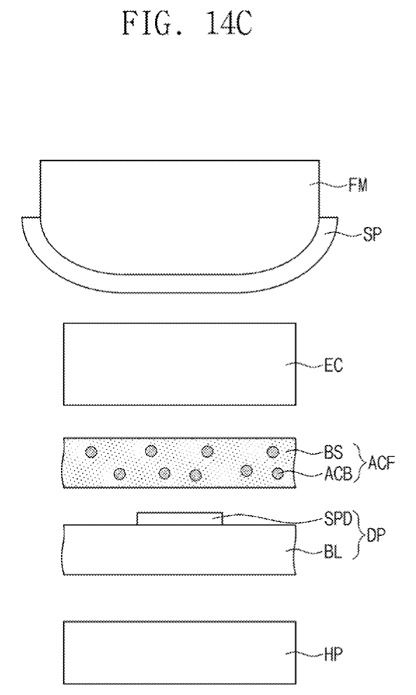

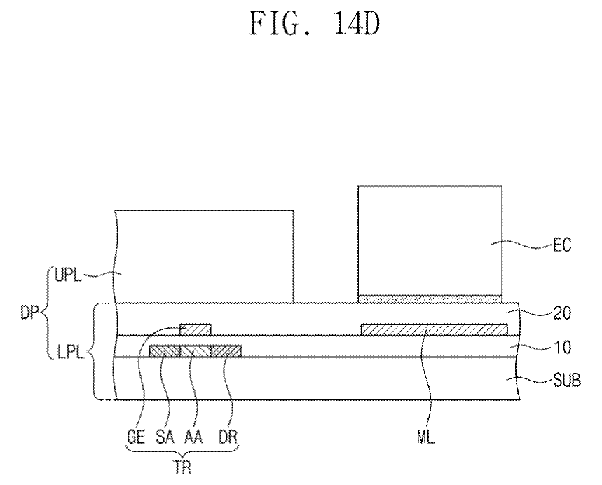

FIGS. 14A - 14D are cross-sectional views illustrating some processes of a method of manufacturing an electronic apparatus according to one or more embodiments. In FIGS. 14A - 14D, the same/similar reference numerals denote the same/similar elements in FIGS. 6A -6D and 7 - 13, and thus, detailed descriptions of the same element will be omitted.

Referring to FIGS. 14A and 14B, a lower substrate LPL and an upper substrate UPL may be sequentially formed on a base substrate SUB in which a display area DA and a driving area DRA are disposed. In this case, the display area DA may correspond to the display area DA of FIG. 12, and the driving area DRA may correspond to the driving area DRA of FIG. 12. Further, the lower substrate LPL may correspond to the substrate BL and a portion of the circuit element layer DP-CL of FIG. 7, and the upper substrate UPL may correspond to a remaining portion of the circuit element layer DP-CL, the display element layer DP-OLED, and the encapsulation layer TFL of FIG. 7.

For convenience of explanation, some components of the circuit element layer DP-CL of FIG. 7 are omitted in FIG. 14A. The base substrate SUB of FIG. 14A may correspond to the substrate BL and the buffer layer BFL of FIG. 7.

The circuit element layer DP-CL (refer to FIG. 7) may include a transistor TR and a wiring layer ML. The transistor TR may be formed in the display area DA, and the wiring layer ML may be formed in the driving area DRA. In the present embodiments, the transistor TR and the wiring layer ML may be formed substantially simultaneously. For example, a gate electrode GE of the transistor TR and the wiring layer ML may be formed through a same process and may include a same conductive material. For example, the gate electrode GE and the wiring layer ML may be formed of a metal or metal alloy such as molybdenum (Mo), aluminum (Al), or titanium (Ti).

Referring to FIGS. 14C and 14D, an electronic component EC may be bonded to the circuit element layer DP-CL by a connection member ACF. FIG. 14C shows a process of bonding the electronic component EC to the wiring layer ML of the circuit element layer DP-CL formed in the driving area DRA using a bonding device.

The connection member ACF may be an anisotropic conductive film (ACF) that includes a solder. The connection member ACF may be manufactured and provided in a rolled form. The connection member ACF may be provided in a film form and may be pre-laminated onto the display panel DP where the circuit element layer DP-CL is formed. Further, since conductive balls ACB included in the connection member ACF react quickly to heat and pressure, bonding may be completed in a relatively short time of about 7 seconds to about 10 seconds.

The process of bonding the electronic component EC may be performed at a temperature from about 140 degrees Celsius to about 180 degrees Celsius. The use of the anisotropic conductive film including the solder enables a stable connection at a relatively low temperature, and thus, it is advantageous in reducing thermal damage to the circuit element layer DP-CL or the electronic component EC.

The bonding of the electronic component EC to the circuit element layer DP-CL may include applying a pressure to bring the electronic component EC into contact with the circuit element layer DP-CL using a silicon pad SP and applying heat to a lower portion of the substrate BL to form an electrical connection between the electronic component EC and the circuit element layer DP-CL.

The silicon pad SP may be fixed by an upper fixing member FM. The upper fixing member FM may move in a downward direction (or the third direction DR3) to directly press the electronic component EC through the silicon pad SP, and thus, the electronic component EC may be adhered to the circuit element layer DP-CL. The silicon pad SP may have elasticity. The silicon pad SP may include a material whose shape is easily deformed by pressure, and a composition of the silicon pad SP may not be particularly limited. Since the silicon pad SP pressing the upper side of the electronic component EC has elasticity, damage to the electronic component EC or the circuit element layer DP-CL may be prevented.

The applying of the heat to the lower portion of the substrate BL may be performed by a back-up heating method, in which a heater plate HP is disposed under the substrate BL, and thus the heat may be transferred from a bottom upwards. In this case, a uniform temperature may be provided to the entire substrate BL, and connection failures due to temperature variations during the bonding process may be prevented. In addition, as the heat and pressure are simultaneously applied, activation of conductive particles may be facilitated, and stable electrical connections may be formed.

The electronic component EC may include bump electrodes, each bump electrode may be electrically connected to a corresponding display pad SPD of the display pads SPD, and the connection member ACF may be disposed between the bump electrode and the display pad SPD. In this case, the display pad SPD may be one of the display pads SPD in FIG. 6 and may be aligned and electrically connected with the bump electrodes of the electronic component EC. As the conductive particles within the connection member ACF are activated by the pressure and heat, a path through which current flows may be formed between the bump electrode and the display pad SPD. Accordingly, a stable signal transmission path may be secured between the electronic component EC and the display panel DP.

In the present embodiments, a separate circuit board to mount the electronic component EC may be omitted, and thus, a process of mounting the electronic component using a high-temperature reflow method may be omitted. Accordingly, possibility of thermal stress on materials or deformation of the substrate BL may be reduced.

As an example, in a structure where the separate circuit board is formed and the electronic component is mounted on this circuit board, a high-temperature reflow SMT (surface mount technology) process at about 280 degrees Celsius may be required. This may cause defects such as variations due to material elongation and warpage of the circuit board.

However, according to the present embodiments, the high-temperature reflow SMT process may be omitted, and thus, the defects may be effectively prevented and the manufacturing method may be simplified.

Although example embodiments of the disclosure have been described, it is understood that the disclosure may not be limited to these embodiments but various changes and modifications can be made by one ordinary skilled in the art within the spirit and scope of the disclosure as hereinafter claimed. Therefore, the disclosed subject matter should not be limited to any single embodiment described herein, and the scope of the disclosure shall be determined according to the attached claims.

What is claimed is:

1. An electronic apparatus comprising:
a substrate;
a circuit element layer on the substrate, the circuit element layer comprising a pixel driver comprising a transistor and a component driver spaced apart from the pixel driver;
a display element layer on the circuit element layer, the display element layer comprising a light emitting element connected to the pixel driver;
an encapsulation layer on the display element layer;
a first electronic component on the substrate; and
a connection member electrically connecting the component driver and the first electronic component,
wherein the component driver comprises:
a wiring layer; and
a pad on the wiring layer, the pad contacting the connection member, and
wherein the wiring layer is at a same layer as a gate electrode of the transistor.

2. The electronic apparatus of claim 1, wherein the component driver is spaced apart from the encapsulation layer in plan view.

3. The electronic apparatus of claim 1, wherein the wiring layer comprises:
a first wiring layer at a same layer as the gate electrode; and
a second wiring layer between the first wiring layer and the pad, and
wherein the first wiring layer, the second wiring layer, and the pad are connected through at least one insulating layer.

4. The electronic apparatus of claim 1, wherein the pad comprises at least one of titanium (Ti), aluminum (Al), and molybdenum (Mo).

5. The electronic apparatus of claim 1, wherein an insulating comprising an opening is between the wiring layer and the pad, and the pad is electrically connected to the wiring layer through the opening.

6. The electronic apparatus of claim 1, wherein the connection member is an anisotropic conductive film comprising a solder.

7. The electronic apparatus of claim 1, further comprising a circuit board on which a second electronic component is mounted.

8. The electronic apparatus of claim 1, further comprising:
a first connection line connecting the component driver and a gate driver;
a second connection line connecting the component driver and a driving chip; and
a third connection line connecting the component driver and the display element layer.

9. An electronic apparatus comprising:
a substrate comprising a display area and a driving area;
a driving chip in the driving area;
a first electronic component in the driving area; and
a connection member between the substrate and the first electronic component,
wherein the driving area comprises:
a chip pad part connected to the driving chip and comprising a first layer and a second layer on the first layer; and
a component driver connected to the first electronic component,
wherein the component driver comprises:
a wiring layer comprising a plurality of conductive layers; and
component pads on the wiring layer, at least one of the components pads contacting the connection member, and
wherein at least one of the conductive layers is at a same layer as the first layer, and the component pads are at a same layer as the second layer.

10. The electronic apparatus of claim 9, wherein the chip pad part and the component pads comprise at least one of titanium (Ti), aluminum (Al), and molybdenum (Mo).

11. The electronic apparatus of claim 9, wherein an insulating layer comprising an opening is between the wiring layer and the component pads, and the component pads are electrically connected to the wiring layer through the opening.

12. The electronic apparatus of claim 9, wherein the connection member is an anisotropic conductive film comprising a solder.

13. The electronic apparatus of claim 9, further comprising a circuit board on which a second electronic component is mounted.

14. The electronic apparatus of claim 13, wherein the driving area comprises a recess portion having a concave shape in plan view, and the circuit board is at the recess portion.

15. A method of manufacturing an electronic apparatus, comprising:
forming a circuit element layer on a substrate comprising a display area and a driving area;
forming a display element layer on the circuit element layer;
forming an encapsulation layer on the display element layer; and
bonding an electronic component to the circuit element layer using a connection member,
wherein the forming the circuit element layer comprises:
forming a transistor in the display area; and
forming a wiring layer in the driving area, and
wherein the forming the wiring layer is simultaneously performed with the forming the transistor.

16. The method of claim 15, further comprising bonding a driving chip to the circuit element layer,
wherein the bonding the electronic component is performed after the bonding the driving chip.

17. The method of claim 15, wherein the connection member is an anisotropic conductive film comprising a solder.

18. The method of claim 17, wherein the bonding the electronic component is performed at a temperature from 140 degrees Celsius to 180 degrees Celsius.

19. The method of claim 15, wherein the bonding the electronic component comprises:
pressing the electronic component using a silicon pad to allow the electronic component to contact the circuit element layer; and
applying heat to a lower portion of the substrate to form an electrical connection between the electronic component and the circuit element layer.

20. The method of claim 15, further comprising:
grinding at least one side of the substrate to form a portion having a concave shape in plan view; and
forming a circuit board,
wherein the circuit board is disposed at the portion having the concave shape.
